(19) United States
(12) Patent Application Publication
(10) Pub. No.: US 2025/0226804 A1
(43) Pub. Date: Jul. 10, 2025

(54) POWER SPLITTER AND A POWER AMPLIFIER

(71) Applicant: Huawei Technologies Co., Ltd., Shenzhen (CN)

(72) Inventors: Shi Cheng, Kista (SE); Song Li, Chengdu (CN); Ruiming Mo, Shanghai (CN); Tomasz Kaczkowski, Kista (SE)

(21) Appl. No.: 19/094,202

(22) Filed: Mar. 28, 2025

Related U.S. Application Data
(63) Continuation of application No. PCT/EP2022/077371, filed on Sep. 30, 2022.

(51) Int. Cl. H03F 3/60; H03F 1/56; H03F 3/24

(52) U.S. Cl. CPC H03F 3/602; H03F 1/565; H03F 3/245; H03F 2200/192

(57) ABSTRACT

Embodiment of the disclosure relate to power splitter comprising a first separation block comprising an input and a first output, the first separation block being configured to receive an input signal via the input and forward the input signal. The power splitter further comprises a second output and a first non-linear impedance connected to the first separation block. The first non-linear impedance is configured to reflect a reflection signal of the input signal to the first output and forward a forward signal of the input signal to the second output, wherein a power ratio between the reflection signal and the forward signal is based on a configuration of the first non-linear impedance.

### CROSS-REFERENCE TO RELATED APPLICATIONS

This application is a continuation of International Application No. PCT/EP2022/077371, filed on Sep. 30, 2022, the disclosure of which is hereby incorporated by reference in its entirety.

### TECHNICAL FIELD

Embodiments of invention relate to a power splitter. Furthermore, embodiments of the invention also relate to a power amplifier comprising such a power splitter.

### BACKGROUND

Power splitters are devices that split an input signal into two or more output signals. Power splitters are common in power amplifiers (PAS) for radio frequency (RF) applications which are extensively used in communication devices for telecommunications, such as base stations.

High-order modulation schemes widely used in telecommunication infrastructure networks result in high peak-to-average (PAR) modulated signals, e.g., 8 or 9 dB of PAR. PAs are the most power consuming building blocks in radio base stations thus increasing demand on high efficiency within a wide output power dynamic range, e.g., high efficiency from 8-9 dB back-off to peak power.

Conventional PA solutions for efficiency power enhancement include power segmentation to employ multiple small PAs based on advanced PA architectures, e.g., Doherty, Load Modulated Balanced Amplifier (LMBA), out-phasing, etc. Dedicated driving signals with tailored amplitude and phase, preferably, power dependent non-linear amplitude and phase are needed for optimal PA performance, e.g., efficiency, gain, peak power, and linearity.

### SUMMARY

An objective of embodiments of the invention is to provide a solution which mitigates or solves the drawbacks and problems of conventional solutions.

Another objective of embodiments of the invention is to provide a power splitter solution simple to implement and to produce.

The above and further objectives are solved by the subject matter of the independent claims. Further embodiments of the invention can be found in the dependent claims.

According to a first aspect of the invention, the above mentioned and other objectives are achieved with a power splitter comprising:
a first separation block comprising an input and a first output, the first separation block being configured to receive an input signal via the input and forward the input signal;
a second output; and
a first non-linear impedance connected to the first separation block and configured to reflect a reflection signal of the input signal to the first output and forward a forward signal of the input signal to the second output, wherein a power ratio between the reflection signal and the forward signal is based on a configuration of the first non-linear impedance.

An advantage of the power splitter according to the first aspect is that it is simple to implement. Further, less components are needed for producing the power splitter according to the first aspect compared to conventional solutions. This also implies lower cost when producing the disclosed power splitter.

In an implementation form of a power splitter according to the first aspect, the first non-linear impedance is connected to the second output via a linear impedance; and wherein the power ratio is based on the configuration of the first non-linear impedance and a configuration of the linear impedance.

An advantage with this implementation form is that by having a linear impedance connected to the second output impedance matching with a circuit connected to the second output is possible. Further, the power ratio can be designed by proper selection of the configuration of the linear impedance.

In an implementation form of a power splitter according to the first aspect, the reflection signal and the forward signal are non-linear in amplitude and phase with respect to the input signal.

In an implementation form of a power splitter according to the first aspect, the non-linear impedance comprises at least one diode connected in a shunt configuration or in a series configuration.

In an implementation form of a power splitter according to the first aspect, the non-linear impedance comprises two diodes connected in a series anti-parallel configuration or in a shunt anti-parallel configuration.

An advantage with this implementation form is that the non-linear change of the output signals at the first and second outputs is larger compared to a single diode configuration. Further, less even harmonic distortion is possible.

In an implementation form of a power splitter according to the first aspect, the two diodes are Schottky diodes.

An advantage with this implementation form is that Schottky diodes have a short response time thus suitable for high modulation bandwidth input signals.

In an implementation form of a power splitter according to the first aspect, the power splitter further comprises at least one second non-linear impedance connected to the first separation block, and wherein the first separation block is configured to forward a first part of the forward signal to the first non-linear impedance and forward a second part of the forward signal to the second non-linear impedance.

An advantage with this implementation form is that multiple output signals can be provided.

In an implementation form of a power splitter according to the first aspect, the first non-linear impedance is configured to reflect a reflection signal of the first part of the forward signal to the first output, and forward a forward signal of the first part of the forward signal to the second output; and the second non-linear impedance is configured to reflect a reflection signal of the second part of the forward signal to the first output, and forward a forward signal of the second part of the forward signal to a third output.

In an implementation form of a power splitter according to the first aspect, the power splitter further comprises a second separation block connected to the first non-linear impedance, the second non-linear impedance, and the second output, respectively, wherein the second separation block is configured to combine a forward signal of the first part of the forward signal from the first non-linear impedance and a forward signal of the second part of the forward signal from the second non-linear impedance into a combined signal and forward the combined signal to the second output.

In an implementation form of a power splitter according to the first aspect, the second separation block is connected to a reference ground via a linear impedance.

In an implementation form of a power splitter according to the first aspect, the first separation block is a 3-dB hybrid coupler and the second separation block is a 3-dB hybrid combiner.

An advantage with this implementation form is that this implementation form is less sensitive to impedance mismatch if an external circuit is connected to the second output.

According to a second aspect of the invention, the above mentioned and other objectives are achieved with a power amplifier comprising a power splitter according to embodiments of the invention.

In an implementation form of a power amplifier according to the second aspect, the power amplifier is a multi-input power amplifier.

Further applications and advantages of embodiments of the invention will be apparent from the following detailed description.

### BRIEF DESCRIPTION OF THE DRAWINGS

The appended drawings are intended to clarify and explain different embodiments of the invention, in which:

FIG. 1 shows a power splitter comprising two outputs according to embodiments of the invention;

FIG. 2 shows a power splitter comprising two outputs and a linear impedance according to embodiments of the invention;

FIG. 3 shows a power splitter comprising multiples outputs according to embodiments of the invention;

FIG. 4 shows a power splitter comprising two outputs and two separation blocks according to embodiments of the invention;

FIGS. 5 and 6 shows non-linear impedance comprising a series diode(s) configuration according to embodiments of the invention;

FIGS. 7 and 8 show non-linear impedance comprising a shunt diode(s) configuration according to embodiments of the invention;

FIG. 9 shows a power amplifier comprising a power splitter according to embodiments of the invention; and

FIGS. 10 and 11 shows plots of measured NLPS response.

### DETAILED DESCRIPTION OF ILLUSTRATIVE EMBODIMENTS

Conventional power splitters have various technical constraints and implementation issues. Analog power splitters provide constant incident power independent amplitude/phase relation between the output signals, thus providing the optimal driving signals for one instantaneous power level only, and hence compromising the performance elsewhere. Another disadvantage with analog power splitters is the low gain. Digital power splitters on the other hand have the potential to deliver optimal drive signals for all multiple input single output (MISO) PA topologies, power levels, frequencies and temperatures. However, the drawbacks with digital power splitters are system complexity, calibration constraints, high direct current (DC) power consumption, higher footprint, etc.

Thus, an objective of embodiments of the invention is to provide a power splitter that splits an input signal into at least two output signals with non-linear amplitude/phase behavior mimicking the multi-input driving scheme for particular PA. The disclosed power splitter may be implemented autonomously, i.e., without any external control signals except a low complex DC bias voltage for controlling the non-linear components such as diodes. In that way the performance of MISO PA can be similar to multi-input scenarios but having only one transmission (Tx) chain.

Embodiments of the invention therefore relate to a power split which enables non-linear amplitude/phase response with respect to an input power signal. It is accomplished by non-linear components in the form of a non-linear impedance connected to a passive separator block and passive components to ensure bias voltage to the non-linear impedance and proper initial linear amplitude and phase relationships of the output signals. According to embodiments of the invention both a reflected signal from the non-linear impedance and a signal passed-through the non-linear impedance, also denoted a forward signal in this disclosure, are used in the present power splitter.

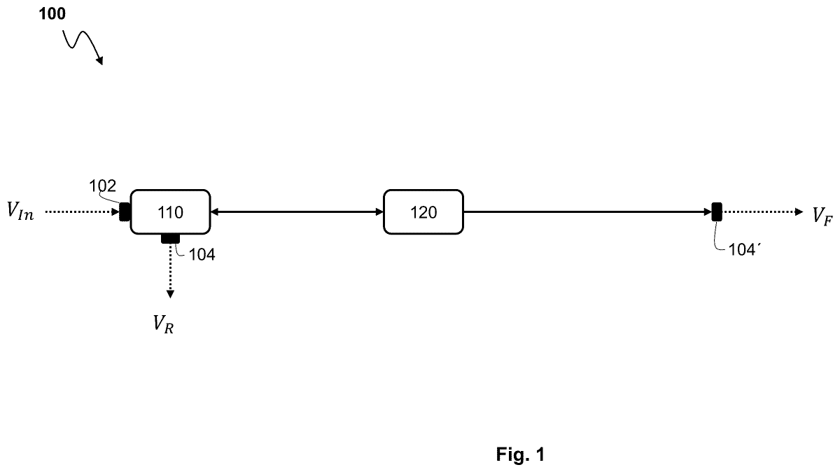

FIG. 1 shows a general block diagram of a power splitter 100 according to embodiments of the invention. The herein disclosed power splitter 100 comprises a first separation block 110 comprising an input 102 and a first output 104. The first separation block 110 is configured to receive an input signal V_{In} via the input 102 and forward the input signal V_{In}. The power splitter 100 further comprises a second output 104′. The power splitter 100 further comprise a first non-linear impedance 120 connected to the first separation block 110 and the non-linear impedance 120 is configured to reflect a reflection signal V_{R} of the input signal V_{In} to the first output 104 and forward a forward signal V_{F} of the input signal V_{In} to the second output 104′. The power ratio between the reflection signal V_{R} and the forward signal V_{F} is based on a configuration of the first non-linear impedance 120. This may be understood such that the power ratio is dependent on the configuration of the first non-linear impedance 120.

The input signal V_{In} passes the first separation block 110 with preferable low insertion loss. This may be achieved by using suitable separation blocks such as isolators, directional couplers and hybrid couplers. The signal from an output of the first separation block 110 goes into an input of non-linear impedance 120 where a reflection signal V_{R} is reflected back to the first output 104 of the first separation block 110 and a forward signal V_{F} is passed through the non-linear impedance 120. The relationships between the input signal V_{In} and the signals at the first output 104 (i.e., reflection signal V_{R}) and the second output 104′ (i.e., forward signal V_{F}) depend on the reflection coefficient at the input of the non-linear impedance 120 and the transmission coefficient of the non-linear impedance 120, which in turn is dependent on a circuit configuration of the non-linear impedance 120. The reflection coefficient is the ratio of reflected signal wave to forward signal wave which in turn depends on the impedance of the separation block 110 and the non-linear impedance 120. If the reflection coefficient is equal to 1 the input signal will be reflected completely as a reflection signal V_{R} while if the reflection coefficient is equal to 0 the input signal will completely pass through the non-linear impedance 120 as a forward signal V_{F}. Mentioned forward signal V_{F} is dependent on the reflection coefficient and the transmission coefficient of the non-linear impedance 120.

By proper tuning of the non-linear impedance 120 low-power and high-power responses of the input signal V_{In} can be designed. The power splitter 100 may be configured to provide a certain low-power response and high-power response, i.e., a power ratio between the low-power response and high-power response. The designed power ratio may be dependent on the application. For example, in MISO PA applications the smallest amplifier delivers power in the low-power region. Thus, the power splitter 100 will deliver most of the drive signal to the smallest amplifier and not deliver or deliver very little drive signal to the larger amplifiers. In high-power regions more drive signal will be delivered to the larger amplifiers and less power to the smallest amplifier.

The first separation block 110 can be any circuit providing separation of the forward signal V_{F} and the reflection signal V_{R} e.g., isolators, directional couplers, 3-dB hybrid couplers. The 3-dB hybrid couplers are widely available, having small footprint and can be obtained at low cost.

The input signal V_{In} may be a modulated continuous wave and instantaneous bandwidth (IBW) signal also denoted a RF signal, which may be defined according to communication standards such as 3GPP 5G new radio (NR). The instantaneous amplitude can be any from 0 to a maximum amplitude value with a certain probability distribution. The modulation scheme depends on the application. The reflection signal V_{R} and the forward signal V_{F} will be non-linear in amplitude and phase with respect to the input signal V_{In}.

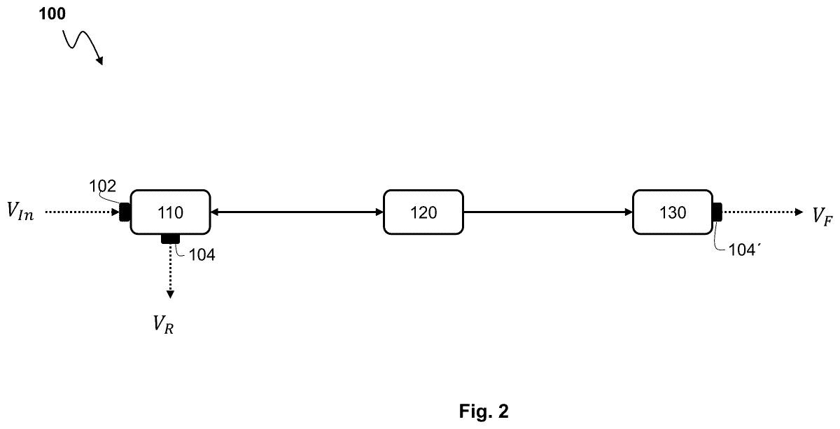

FIG. 2 shows the power splitter 100 in FIG. 1 with the addition of a linear impedance 130 according to embodiments of the invention. Thus, the output of first non-linear impedance 120 is connected to the second output 104′ via a linear impedance 130. Generally, the linear impedance of a power splitter 100 is the impedance that remains unchanged over the operating power range of the power splitter 100 and can be due to transmission lines, R-, L-, C-components, etc. Thus, bias components in the non-linear impedance 120, e.g., parasitic elements (L, C) of a non-linear element, also act as linear impedance. Hence, the linear impedance of the power splitter 100 can be considered as the linear impedance in the power range where cascaded electrical components in the power splitter 100 act in a linear fashion. However, by adding a linear impedance 130 the linear amplitude and phase of the forward signal V_{F} can be modified further. The impedance presented at the output of the separation block 110 towards the non-linear impedance 120 defines the reflection coefficient which comprises of cascade of the non-linear impedance 120, the linear impedance 130 and impedance presented at the second output 104′ e.g., by an external circuit connected to the second output 104′. This also means that the ratio between the reflection signal V_{R} and the forward signal V_{F} can be further modified by configuring the linear impedance 130. The output of first non-linear impedance 120 is connected to an input of the linear impedance 130 which implies that the power ratio in this case will be based on the configuration of the first non-linear impedance 120 and the configuration of the linear impedance 130. The configuration of the linear impedance 130 can provide additional functionality such as impedance matching to an external circuit (not shown in the Figs.) connected to the second output 104. The linear impedance 130 may also act as a filter for the output signal from the non-linear impedance 120 if tuned properly. Non-limiting examples of the configuration of the linear impedance 130 are series transmission line with a characteristic impedance resulting in a phase shift, and a circuit comprising passive lumped and distributed electrical elements creating a certain reflection.

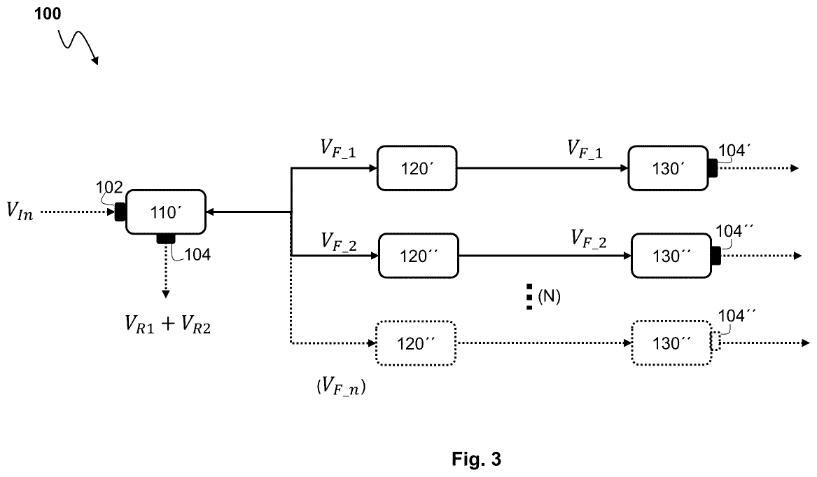

FIG. 3 shows a power splitter 100 comprising multiples outputs according to embodiments of the invention. The power splitter 100 may comprise N number of outputs where N is an integer equal to or larger than 2. Thus a 1-to-N power splitter 100 is herein disclosed. In such an N output configuration of the power splitter 100, the general topology of the power splitter 100 further comprises at least one second non-linear impedance 120″ connected to the first separation block 110′ as shown in FIG. 2. The first separation block 110′ is thus configured to forward a first part V_{F_1} of the forward signal V_{F} to the first non-linear impedance 120′ and forward a second part V_{F_2} of the forward signal V_{F} to an input of the second non-linear impedance 120″.

As illustrated in FIG. 3, the first non-linear impedance 120′ is configured to reflect a reflection signal V_{R1} of the first part V_{F_1} of the forward signal V_{F} to the first output 104. The first non-linear impedance 120′ will also forward a forward signal of the first part V_{F_1} of the forward signal V_{F} to the second output 104′. The second non-linear impedance 120″ will reflect a reflection signal V_{R2} of the second part V_{F_1} of the forward signal V_{F} to the first output 104, and forward a forward signal of the second part V_{F_1} of the forward signal V_{F} to a third output 104″.

By adding additional non-linear impedances and associated outputs, the number of outputs N can be adapted to any suitable PA application. Hence, in general terms the input signal V_{In} will be splitted into N number of signals in the separation block 110 before sent to its respective non-linear impedance illustrated with dashed arrows and blocks in FIG. 3. Thus, without any recombination after the non-linear impedances there will be N number of output signals at its respective output. The N outputs signals will have similar signal responses, but the response might be offset in power. Generally, the non-linear components of the non-linear impedance 120 can be activated at different instantaneous power levels by different applied bias DC voltages. It is further noted in FIG. 3 that each non-linear impedance 120′, 120″ can be connected to its respective output 104′, 104″ via a respective linear impedance 130′, 130″.

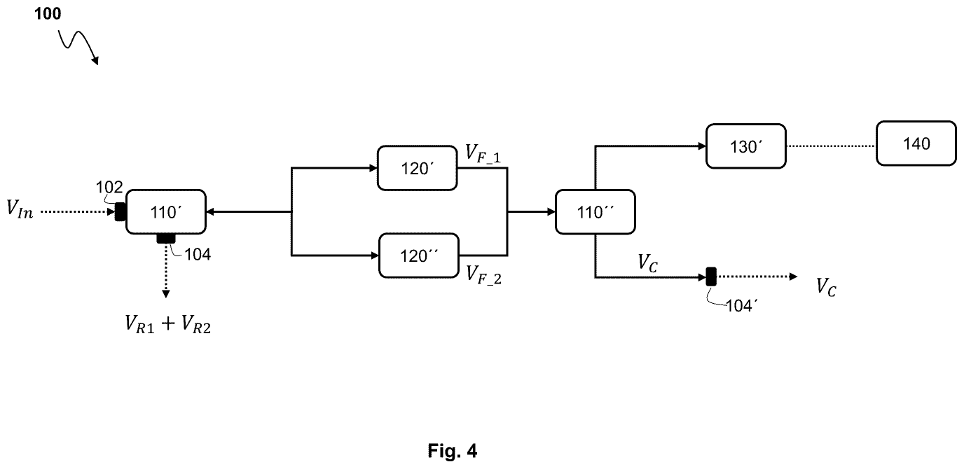

FIG. 4 on the other hand shows a power splitter 100 comprising two outputs and two separation blocks according to further embodiments of the invention. With reference to FIG. 4, the power splitter 100 comprises a second separation block 110″ which is connected to an output of the first non-linear impedance 120′, an output of the second non-linear impedance 120″, and the second output 104′, respectively. The second separation block 110″ is configured to combine a forward signal of the first part V_{F_1} of the forward signal V_{F} from the first non-linear impedance 120′ and a forward signal of the second part V_{F_1} of the forward signal V_{F} from the second non-linear impedance 120″ into a combined signal V_{C} which is forwarded to the second output 104′. It is further be noted that the second separation block 110″ is connected to a reference ground 140 via a linear impedance 130 for a balanced termination.

In embodiments of the invention, the first separation block 110′ is a 3-dB hybrid coupler while the second separation block 110″ is a 3-dB hybrid combiner. In case of 3-dB hybrid coupler used as the first separation block 110′, the input signal will be divided into two branches with the same amplitude but 90 degrees phase offset to each other. Consequently, there will be two separate non-linear impedance blocks 120′, 120″. The signals from the two branches are recombined in the second separation block 110″ into a combined signal V_{C}, in this case an output 3-dB hybrid coupler. As mentioned, the linear impedance 130′ act as a termination and is thus connected to reference ground 140 and hence have another function as the linear impedances in the previous embodiments. In case of recombination, symmetry between the two branches is required since an unbalance in phase and amplitude will appear at the output of the hybrid coupler which will result in power waste.

The embodiment shown in FIG. 4 may be aimed to support a 2-input LMBA with a control amplifier connected to the first output 104 and a balanced amplifier to the second output 104′ when the configuration of the non-linear impedance 120 is a series configuration. For shunt non-linear configuration of the non-linear impedance 120, the connection of control amplifier and balanced amplifier is swapped, i.e., the control amplifier is connected to the second output 104′ and the balanced amplifier is connected to the first output 104. This topology falls into a NLPS-based on hybrid coupler and 2-outputs category.

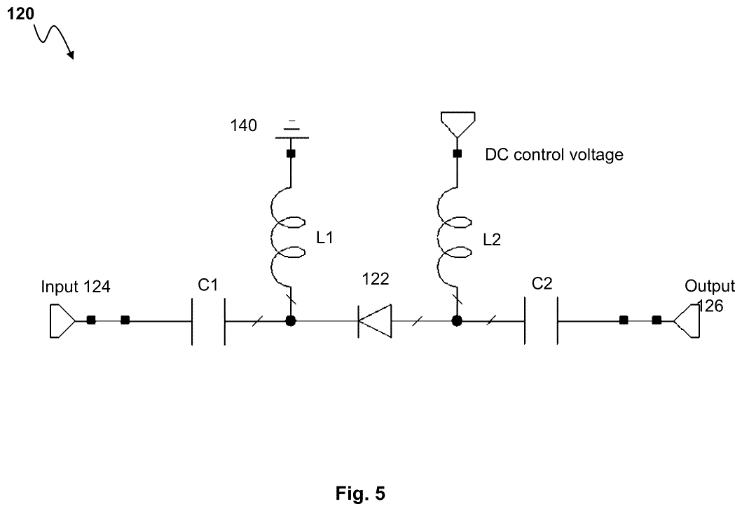

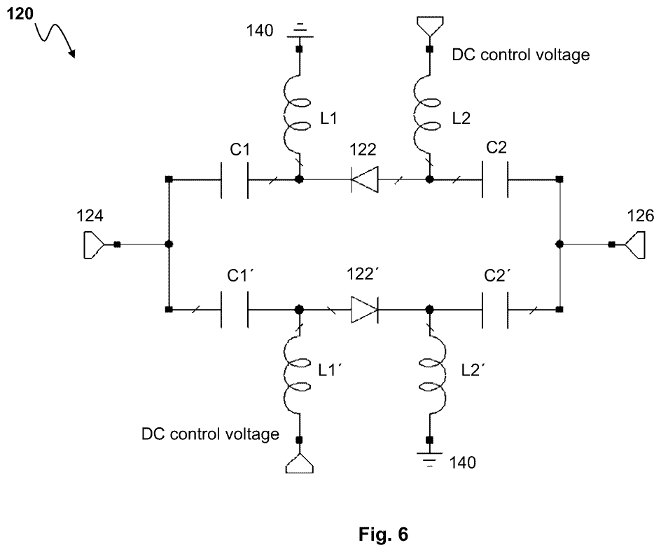

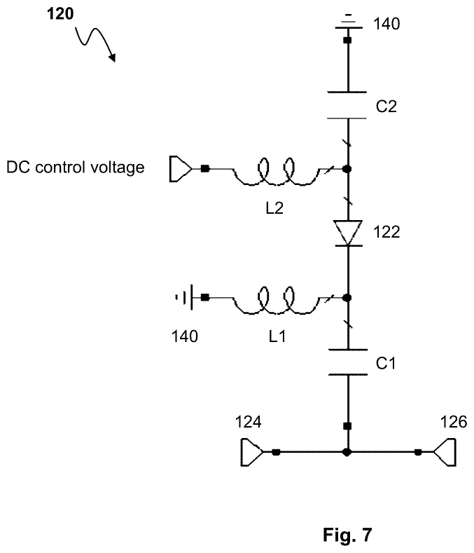

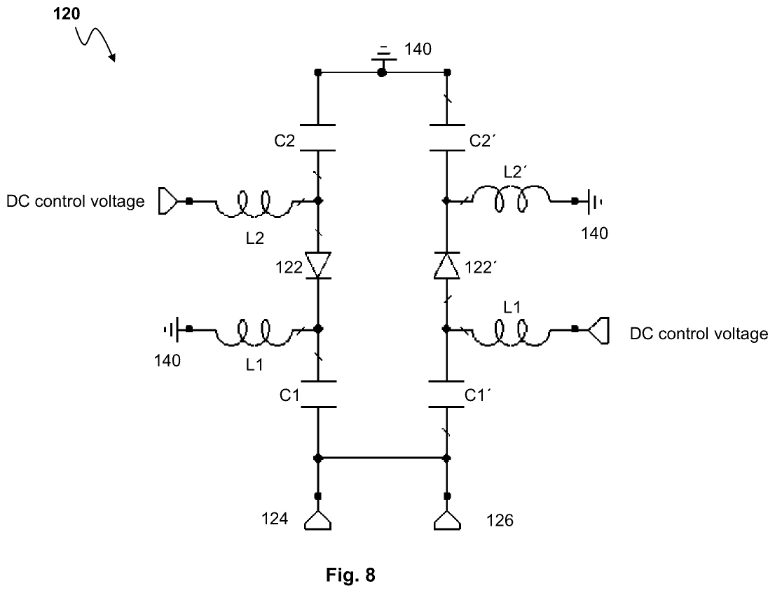

As aforementioned, the power ratio between the reflection signal V_{R} and the forward signal V_{F} is at least partially based on the configuration of the first non-linear impedance 120. Hence, different exemplary configurations of the first non-linear impedance 120 will be described with reference to FIGS. 5-8 in the following disclosure. FIGS. 5 and 6 shows when the non-linear impedance 120 comprises a series diode(s) configuration according to embodiments of the invention while FIGS. 7 and 8 shows when the non-linear impedance 120 comprises a shunt diode(s) configuration according to embodiments of the invention. In general terms, the non-linear impedance 120 comprises at least one diode 122, 122′ connected in a shunt configuration or in a series configuration.

The non-linear impedance 120, can be implemented with diodes, non-linear capacitances, and by passive components such as transmission lines, capacitors, inductors, etc. The inductors L1, L2 in the configuration of the non-linear impedance 120 provides the DC bias voltage to the diode(s) and block the RF signal from going into the DC voltage line. In ideal case the inductors L1, L2 are open circuit, i.e., high impedance, for RF signals and short circuit, i.e., low impedance for DC signals. The function of the capacitors C1, C2 is the opposite to the function of the inductors L1, L2, i.e., to act as an open circuit for DC signals and short circuit for RF signals. In real implementations, the parasitic elements and the transmission lines of the non-linear impedance 120 will all contribute to the linear response of the power splitter 100. It is however noted that the non-linear impedance 120 may be implemented with other types of non-linear elements such as varactors, pin diodes, transistors, etc.

For low input power levels where the diodes 122, 122′ are in high resistance state passive components provides certain reflection for the signals coming out from the first separation block 110. This sets the initial amplitude difference between the signals at the first output 104 and the second output 104′, respectively. Passive components also provide the DC bias voltage for controlling the diodes 122, 122′. For input power levels higher than the turn-on state of the diodes 122, 122″, which is set by diode properties and the applied bias DC voltage, the resistance of the diodes 122, 122″ will go down and the power delivered to the first output 104 will go up while the power delivered to the second output 104′ will go down for shunt diode configuration. For series configuration, the opposite holds true. The phase difference between the signal at the first output 104 and the signal at the second output 104 is also non-linear in this operating region. The non-linear resistance should be able to respond to instantaneous change of the input signal, i.e., multiple of the instantaneous bandwidth (IBW). Thus, the diodes 122, 122′ chosen for the non-linear impedance 120 is in embodiments of the invention a Schottky diode due to fast response time of such diodes. Diodes are used in anti-parallel shunt configuration in order to be effective on both positive and negative parts of instantaneous RF signals. The single diode configuration will only act on one half period of the RF signal wave, i.e., the positive or the negative signal wave depending on the diode orientation. This means lower performance and higher even harmonic distortion compared to the two diodes configuration which acts on the whole period of the RF signal wave.

FIG. 5 shows a single diode 122 in a series configuration. With reference to FIG. 5, the circuit configuration comprises a first capacitor C1, a diode 122 and a second capacitor C2 connected in series between an input 124 and an output 126 of the circuit configuration. A DC control voltage, also denoted DC bias voltage, is connected to the node between the diode 122 and the second capacitor C2 via a second inductance L2. The diode 122 can be reverse biased and the DC bias voltage can be applied from any side of the diode 122 with proper sign, i.e., plus (+) or minus (−). Further, the node between the first capacitor C1 and the diode 122 is connected to reference ground 140 via a first inductor L1. FIG. 6 shows two diodes 122, 122′ connected in a series configuration. Thus, the non-linear impedance 120 in this example comprises two diodes 122, 122′ connected in a series anti-parallel configuration. The circuit in FIG. 6 comprises two serial circuits shown in FIG. 5 connected in parallel between the input 124 and the output 126, however with opposite directed diodes 122, 122′.

For the series diode configuration at low input power, the diodes 122, 122′ will act as high impedance circuits which reflects most of the signal to the first output 104 and pass almost no power through the non-linear impedance 120 to the linear impedance 130 and the second output 104′. However, for the series diode configuration at high input power, the diodes 122, 122′ will act as low impedance circuits thus pass most of the signal to the linear impedance 130 and the second output 104′ and reflect almost no signal to the first output.

FIG. 7 shows a single diode 122 in a shunt configuration. With reference to FIG. 7, a first capacitance C1, a diode 122 and a second capacitance C2 are connected in series between the node between the input 124 and the output 126 and a reference ground 140. Further, a first inductor L1 is connected to a node between the first capacitance C1 and the diode 122 and reference ground 140. A DC control voltage is connected to a node between the second capacitor C2 and the diode via a second inductor L1. FIG. 8 shows two diodes 122, 122′ connected in a shunt anti-parallel configuration. The circuit in FIG. 8 comprises two circuits shown in FIG. 7 connected shunt anti-parallel configuration between the input 124 and the output 126, however with opposite directed diodes 122, 122′.

For the shunt diode configuration at low input power the diodes 122, 122′ will act as high impedance circuits—thus pass most of the signal though the non-linear impedance 120 and reflect almost no signal. However, for the shunt diode configuration at high input power the diodes 122, 122′ will act as low impedance circuits—thus reflect most of the signal and pass almost no signal though the non-linear impedance 120.

It may be noted that in real life implementations, diodes also contain L and C parasitic elements which do not depend on the RF input power. The diode is not open circuit in low RF incident power and is not a short circuit at high RF power. All the elements that are not changing in the operating power region can be treated as linear impedance. The diode resistance will depend on RF power—it is thus considered as non-linear impedance in this context.

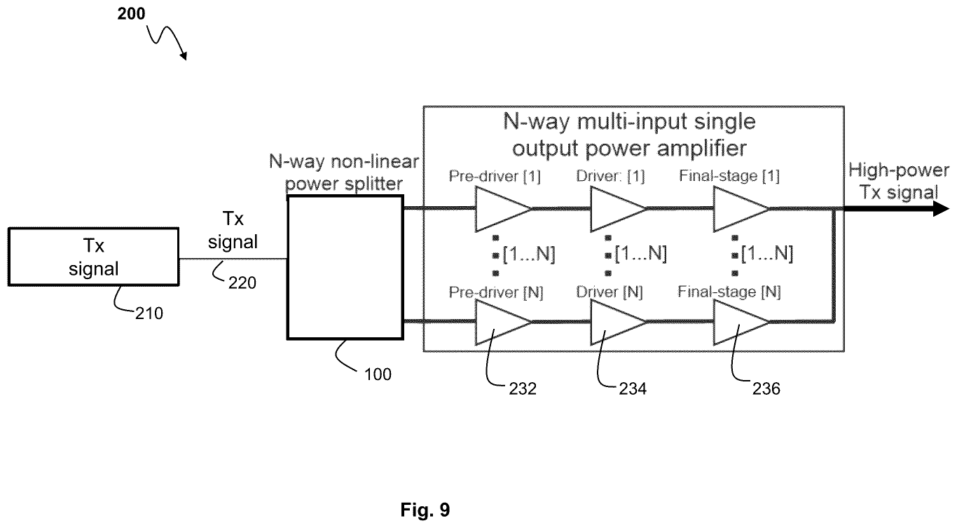

FIG. 9 shows a N-way multi-input power amplifier 200 driven by a single Tx signal from a signal provider block 210 to a power splitter 100 according to embodiments of the invention via a signal line 220. The power amplifier 200 may be used in a communication device such as a base station of a communication network. Each amplifier chain in the power amplifier 200 comprises of a pre-driver 232, a driver 234 and final stage 236. The number of amplifier chains may be different for different implementations depending on the application. All amplifier chains are connected to a common node outputting a high-power Tx with help of the combiner (not shown) before sent to next processing block(s) which can be a filter, an antenna, etc. (not shown). The amplifier chains might interact with each other or be isolated from each other depending on the principle of operation of the particular MISO PA. The principle of operation is set by combiner properties and drive signals applied to each amplifier chain. In conventional power splitters, there will be more than one small-signal Tx drive signal 220. Any additional Tx drive signals will add more digital infrastructure components, modulators, filters, etc., which results in higher cost, DC power consumption, footprint and complexity. Thus, the power splitter 100 according to the invention reduces the number of components while still maintaining high performance.

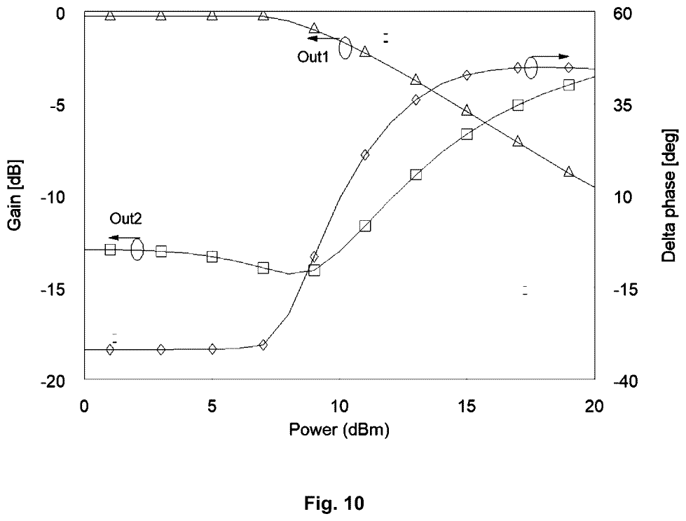

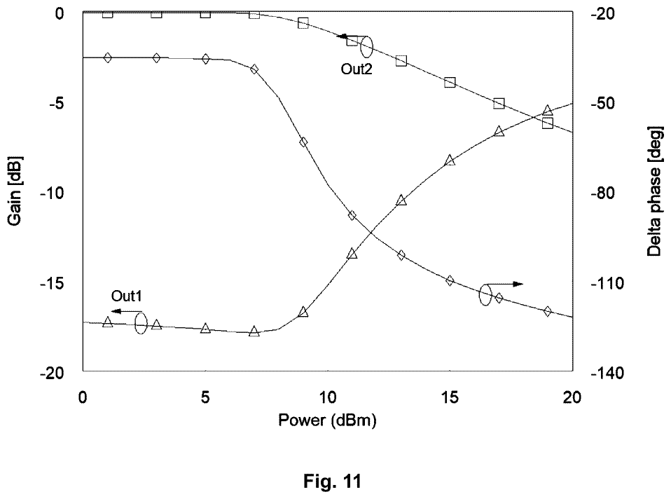

FIGS. 10 and 11 shows plots of measured response of embodiments of the power splitter 100 where FIG. 10 shows the results for the anti-parallel series Schottky diodes configuration while FIG. 11 shows the results for the anti-parallel shunt Schottky diodes configuration. The x-axis shows the input power in dBm, the right y-axis the phase difference between a first output Out1 and a second output Out2 and the left y-axis the gain in dB. From FIG. 10 it may be derived that up to about 7 dBm of input power the impedance of the non-linear impedance is very high, thus most of the signal is reflected to the first output Out1. From about 7 dBm and up the impedance of the non-linear impedance is getting lower which means that more power goes to the second output Out2 and less power to the first output Out1. The phase response is non-linear in this power region. From FIG. 11 it may be derived that up to about 7 dBm of the input power the impedance of the non-linear block is very high, thus most of the power goes to the second output Out2. From about 7 dBm and up the impedance of the non-linear block is getting lower which means that more power is reflected to the first output Out1 and less power is directed to the second output Out2. The phase response is non-linear in this power region.

Finally, it should be understood that the invention is not limited to the embodiments described above, but also relates to and incorporates all embodiments within the scope of the appended independent claims.

1.-20. (canceled)

21. A power splitter comprising:
a first separation block comprising an input and a first output, the first separation block being configured to receive an input signal via the input and forward the input signal;
a second output; and
a first non-linear impedance connected to the first separation block and configured to reflect a reflection signal of the input signal to the first output and forward a forward signal of the input signal to the second output, wherein a power ratio between the reflection signal and the forward signal is based on a configuration of the first non-linear impedance.

22. The power splitter according to claim 21, wherein the first non-linear impedance is connected to the second output via a linear impedance, and wherein the power ratio is based on the configuration of the first non-linear impedance and a configuration of the linear impedance.

23. The power splitter according to claim 21, wherein the reflection signal and the forward signal are non-linear in amplitude and phase with respect to the input signal.

24. The power splitter according to claim 21, wherein the first non-linear impedance comprises at least two diodes connected in a shunt configuration or in a series configuration.

25. The power splitter according to claim 24, wherein the first non-linear impedance comprises two diodes connected in a series anti-parallel configuration or in a shunt anti-parallel configuration.

26. The power splitter according to claim 25, wherein the two diodes are Schottky diodes.

27. The power splitter according to claim 21, further comprising at least one second non-linear impedance connected to the first separation block,
wherein the first separation block is configured to forward a first part of the forward signal to the first non-linear impedance and forward a second part of the forward signal to the second non-linear impedance.

28. The power splitter according to claim 27, wherein:
the first non-linear impedance is configured to reflect a first reflection signal of the first part of the forward signal to the first output, and forward a first forward signal of the first part of the forward signal to the second output; and
the second non-linear impedance is configured to reflect a second reflection signal of the second part of the forward signal to the first output, and forward a second forward signal of the second part of the forward signal to a third output.

29. The power splitter according to claim 28, further comprising:
a second separation block connected to the first non-linear impedance, the second non-linear impedance, and the second output, respectively, wherein the second separation block is configured to combine the first forward signal of the first part of the forward signal from the first non-linear impedance and the second forward signal of the second part of the forward signal from the second non-linear impedance into a combined signal and forward the combined signal to the second output.

30. The power splitter according to claim 29, wherein the second separation block is connected to a reference ground via a linear impedance.

31. The power splitter according to claim 29, wherein the first separation block is a 3-dB hybrid coupler, and the second separation block is a 3-dB hybrid combiner.

32. A power amplifier comprising a power splitter, wherein the power splitter comprises:
a first separation block comprising an input and a first output, the first separation block being configured to receive an input signal via the input and forward the input signal;
a second output; and
a first non-linear impedance connected to the first separation block and configured to reflect a reflection signal of the input signal to the first output and forward a forward signal of the input signal to the second output, wherein a power ratio between the reflection signal and the forward signal is based on a configuration of the first non-linear impedance.

33. The power amplifier according to claim 32, wherein the first non-linear impedance is connected to the second output via a linear impedance, and wherein the power ratio is based on the configuration of the first non-linear impedance and a configuration of the linear impedance.

34. The power amplifier according to claim 32, wherein the reflection signal and the forward signal are non-linear in amplitude and phase with respect to the input signal.

35. The power amplifier according to claim 32, wherein the first non-linear impedance comprises at least two diodes connected in a shunt configuration or in a series configuration.

36. The power amplifier according to claim 35, wherein the first non-linear impedance comprises two diodes connected in a series anti-parallel configuration or in a shunt anti-parallel configuration.

37. The power amplifier according to claim 36, wherein the two diodes are Schottky diodes.

38. The power amplifier according to claim 32, further comprising at least one second non-linear impedance connected to the first separation block,
wherein the first separation block is configured to forward a first part of the forward signal to the first non-linear impedance and forward a second part of the forward signal to the second non-linear impedance.

39. The power amplifier according to claim 38, wherein:
the first non-linear impedance is configured to reflect a first reflection signal of the first part of the forward signal to the first output, and forward a first forward signal of the first part of the forward signal to the second output; and
the second non-linear impedance is configured to reflect a second reflection signal of the second part of the forward signal to the first output, and forward a second forward signal of the second part of the forward signal to a third output.

40. The power amplifier according to claim 32, wherein the power amplifier is a multi-input power amplifier.
